(19) United States
(12) Patent Application Publication
(10) Pub. No.: US 2014/0231846 A1
(43) Pub. Date: Aug. 21, 2014

(54) LIGHT EMITTING MODULE

(71) Applicant: LEXTAR ELECTRONICS CORPORATION, Hsinchu (TW)

(72) Inventor: Ching-Yao Lin, New Taipei City (TW)

(73) Assignee: LEXTAR ELECTRONICS CORPORATION, Hsinchu (TW)

(21) Appl. No.: 13/962,589

(22) Filed: Aug. 8, 2013

(30) Foreign Application Priority Data
Feb. 20, 2013 (TW) 102105857

(51) Int. Cl. H01L 33/58

(52) U.S. Cl. CPC H01L 33/58
USPC 257/98

(57) ABSTRACT

A light emitting module includes a light-emitting unit, a wavelength converting element and an optical convergent element for partially or totally converting the wavelength of incident light. The light-emitting unit includes a light-emitting element which emits a first light, the wavelength converting element and an optical convergent element disposed in a light path of the first light from the light-emitting element, such that the first light is converted into a particular light at a specific area with a reduced beam diameter after passing through the optical convergent element and before entering the wavelength converting element.

### RELATED APPLICATIONS

This application claims priority to Taiwan Application Serial Number 102105857, filed Feb. 20, 2013, which is herein incorporated by reference.

### BACKGROUND

1. Field of Invention

The present invention relates to a light emitting module. More particularly, the present invention relates to a light-emitting module having an optical convergent element.

2. Description of Related Art

Light sources used in modern lighting devices normally includes incandescent light, halogen light, fluorescent light, cold cathode fluorescent lighting (CCFL), light emitting diode (LED) and so on. Once the light sources have been made, it is hard to modify their color temperature and color rendering. General incandescent light bulbs have good color temperature and color rendering, but suffer a relatively short lifetime and low luminous efficiency. Compare with incandescent lamps, halogen lamps have improved the shortcoming of lifetime and luminous efficiency, but have problems about high heat generation and ultraviolet. In addition, traditional lighting devices with the application of an incandescent principle have limitations of high heat generation, and fixed color temperature and color rendering after they leave the factory. As to the CCFL, it has problems about environment protection because containing mercury, and also has the problems about insufficient color temperature and color rendering.

In recent years, the LED has the predominance of other traditional lighting sources because of its merits of small volume, long lifetime, short reaction time, and the environmental protection without contamination problem about e.g. thermal radiation, mercury and other toxic substance. Two approaches are used in the industry now to emit white LED light, in which one is to combine different wavelength emitting LED chips, and another is using wavelength division converting materials, like semiconductor, phosphor or dye, cooperate with a monochromatic light LED.

However, the emergent LED lighting sources still cannot totally replace traditional lighting sources. The main reason is that the commercialized LED lighting production lacking of the feature to present consistent color temperature accurately, so that inevitably having color temperature differences between the productions. A remote phosphor technique has been provided to solve the non-consistent color temperature problem. However, because the usage of the phosphor in remote phosphor is more than traditional LED, using this technique on fluorescent tube need large area of phosphor, and made high raise in cost inevitably.

### SUMMARY

In this regard, one embodiment of the present invention provides a light emitting module, so as to mainly apply an optical convergence component to converge the light beams emitted by the light-emitting element in the light emitting module. As such, the required area phosphor is decreased.

To reach the abovementioned purpose, according to one embodiment of the present invention, a light emitting module includes a light-emitting unit, an optical convergent element, and a wave converting element. The light-emitting unit includes a light-emitting element. In which the light-emitting element emits a first light in wavelength λ₁, and the optical convergent element disposed in a light path of the first light from the light-emitting element, making the first light in wavelength λ₁ converge to a specific area. After passing through the optical convergent element, the first light becomes a second light in wavelength λ₁ of the specific area. The wave converting element is disposed in a light path of the second light from the optical convergent element, and the wave converting element having a wave converting material and an incident plane, making the second light in wavelength λ₁, after entering the incident plane and the wavelength converting element, be converted to a third light in wavelength λ₂.

In some embodiments of the present invention, the light-emitting unit also have a reflecting element, surrounding the abovementioned light-emitting unit and directing the first light in the wavelength λ₁ emitted from the light-emitting element to be reflected first by the reflecting element, and then to enter the optical convergent element.

In some embodiments of the present invention, the light emitting module, further including a diffusion element, disposed on the top of the emitting direction of the third light in wavelength λ₂, to uniformly diffuse and receive the third light in wavelength λ₂, which passing through the wavelength converting element.

In some embodiments of the present invention, the area of the incident plane for the wavelength converting element, substantially equal to the specific area of the second light in the wavelength λ₁, which comes from the optical convergent element.

In some embodiments of the present invention, the wavelength converting element includes: a body; and at least one wavelength converting material, which is separated in the body in a uniform or patterned or laminar way.

In some embodiments of the present invention, the wavelength converting material is one selected from the group consisting of phosphor, dye, pigments, quantum dots (QDs) and combinations thereof.

In some embodiments of the present invention, the phosphor is a phosphor that is capable of emitting visible light; and base on one embodiment of the invention, a light color of the visible light emitted from the phosphor is one selected from the group consisting of red, green, blue and combinations thereof.

In some embodiments of the present invention, the light-emitting element is a light emitting diode chip. According to one embodiment of the invention, the light emitting diode chip is an ultraviolet light chip or a blue light chip.

In some embodiments of the present invention, the optical convergent element is a condensing lens. Following one embodiment of the invention, condensing lens can be one selected from the group consisting of a convex lens, spherical lens, hemispherical lens, spherocylinder lens, cylindrical lens, molded lens, Fresnel lens and combinations thereof. And in another embodiment of the invention, the convex lens is selected from the group consisting of plane-convex lens, double-convex lens, concave-convex lens and combinations thereof.

In some embodiments of the present invention, the light emitting module further includes encapsulating glue, covering the abovementioned light-emitting element.

By the abovementioned embodiments of the present invention, the area of the incident plane used on the wavelength converting element for lens can be reduced effectively. In other words, it can save the wavelength converting material effectively.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a schematic diagram of light emitting module; and

FIG. 2 is a schematic diagram of light emitting module; and

FIG. 3 is a schematic diagram of light emitting module; and

FIG. 4A is a schematic diagram of light emitting module using in a strip lamp; and

FIG. 4B is a schematic diagram of light emitting module using in a strip lamp according to one embodiment of this invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

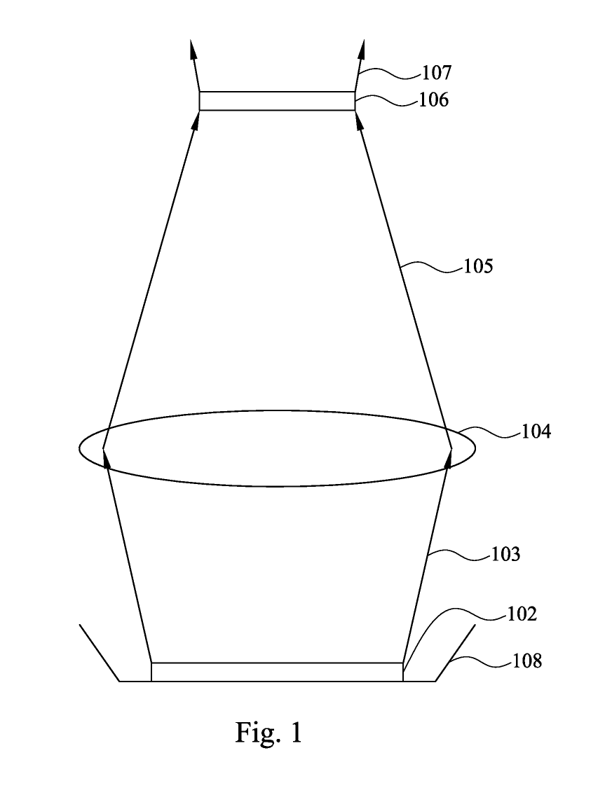

FIG. 1 is a schematic diagram of light emitting module according to one embodiment of this invention. As shown in FIG. 1, the light emitting module of this embodiment includes a light-emitting unit, an optical convergent element 104 and a wavelength converting element 106. In which, the light-emitting unit includes a light-emitting element 102. The light-emitting element 102 emits a first light 103 with wavelength λ₁, passing through an optical convergent element 104, which disposed in a light path of the first light 103 from the light-emitting element 102, making the first light 103 in wavelength λ₁ converge to a specific area, and the first light 104 becomes a second light 105 in wavelength λ₁. The second light 105 emits from the optical convergent element 104, irradiating on an incident plane of the wavelength converting element 106. Having a wavelength converting material in the wavelength converting element 106 makes the second light 105 in wavelength λ₁, after entering the incident plane and the wavelength converting element 106, be converted to a third light 107 in wavelength λ₂.

According to one embodiment of the present invention, the light-emitting element 102 includes a light emitting diode chip, mounted on a substrate 108. The surface of substrate 108, which the light emitting diode chip mounted, can coat a retro-reflective material layer on it, or the substrate 108 is made by retro-reflective material. In which, the light emitting diode chip may be an ultraviolet light chip or a blue light chip.

According to one embodiment of the present invention, the area of the incident plane on the wavelength converting element 106 , essentially equal to the specific area of the second light 105 in wavelength λ₁, which comes from the optical convergent element 104.

According to one embodiment of the present invention, the wavelength converting element 106 includes a body and at least one wavelength converting material, which is separated in the body in a uniform or graphical or laminar way.

According to one embodiment of the present invention, the light emitting module includes a diffusion element, which is disposed on the top of the emitting direction of the third light 107 in wavelength λ₂, in order to diffuse, unify and receive the third light 107 in wavelength λ₂, which passing through the wavelength converting element.

According to one embodiment of the present invention, the optical convergent element 104 is a condensing lens. In some embodiments of the present invention, the condensing lens is selected from the group consisting of a convex lens, spherical lens, hemispherical lens, spherocylinder lens, cylindrical lens, molded lens, Fresnel lens and combinations thereof. In another embodiment, convex lens is selected from the group consisting of plane-convex lens, double-convex lens, concave-convex lens and combinations thereof.

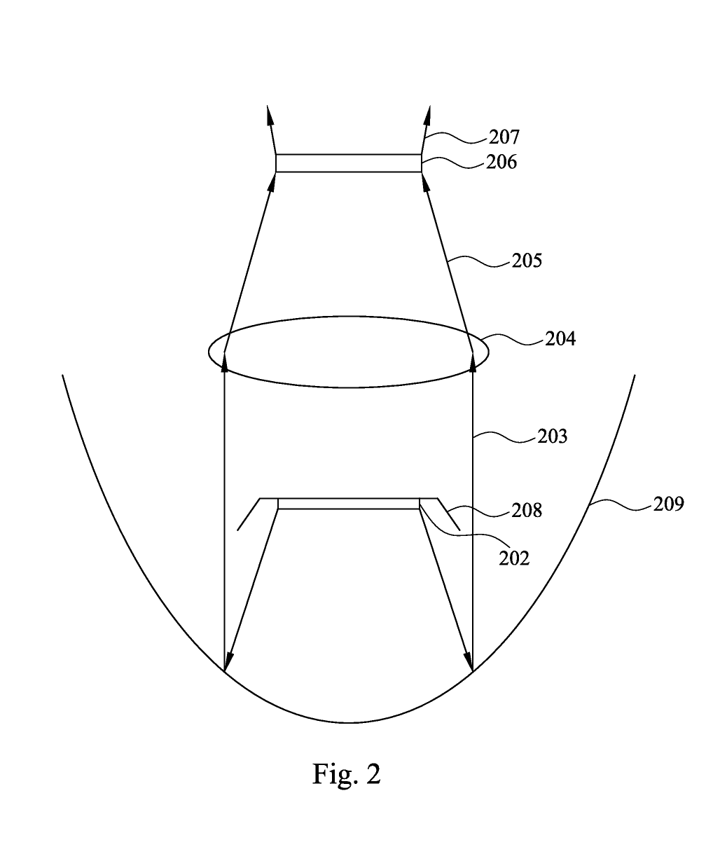

FIG. 2 depicts a schematic diagram of light emitting module according to one embodiment of this invention. As shown in FIG. 2, the light emitting module in the embodiment includes a light unit, an optical convergence element 204, a reflecting element 209 and a wavelength converting element 206. The light unit contains a light-emitting element 202. The light-emitting element 202 emits a first light 203 in wavelength λ₁. The first light 203 in wavelength λ₁ is first reflected by the reflecting element 209, changing the optical pathway, and then passing through the optical convergence element 204. After passing through the optical convergence element 204, the first light 203 in wavelength λ₁ is converged to a specific area and becoming a second light 205 in wavelength λ₁. The second light 205 is first emitted from the optical convergence element 204, then irradiate on an incident plane of a wavelength converting element 206, which includes a wavelength converting material, after passing through the wavelength converting element 206, the second light 205 in wavelength λ₁ is converted to a third light 207 in wavelength λ₂.

According to one embodiment of the present invention, the light-emitting element 202 includes a light emitting diode chip, mounted on a substrate 208. The surface of substrate 208, which the light emitting diode chip mounted, can coat a retro-reflective material layer on it, or the substrate 208 is made by retro-reflective material.

According to one embodiment of the present invention, the area of the incident plane on the wavelength converting element 206, essentially equal to the specific area of the second light 205 in wavelength λ₁, which comes from the optical convergent element 204.

According to one embodiment of the present invention, the wavelength converting element 206 includes a body and at least one wavelength converting material, which is separated in the body in a uniform or graphical or laminar way.

According to one embodiment of the present invention, the light emitting module includes a diffusion element, which is disposed on the top of the emitting direction of the third light 207 in wavelength λ₂, in order to diffuse, unify and receive the third light 207 in wavelength λ₂, which passing through the wavelength converting element.

According to one embodiment of the present invention, the optical convergent element 204 is a condensing lens. In some embodiments of the present invention, the condensing lens is selected from the group consisting of a convex lens, spherical lens, hemispherical lens, spherocylinder lens, cylindrical lens, molded lens, Fresnel lens and combinations thereof. In another embodiment, convex lens is selected from the group consisting of plane-convex lens, double-convex lens, concave-convex lens and combinations thereof.

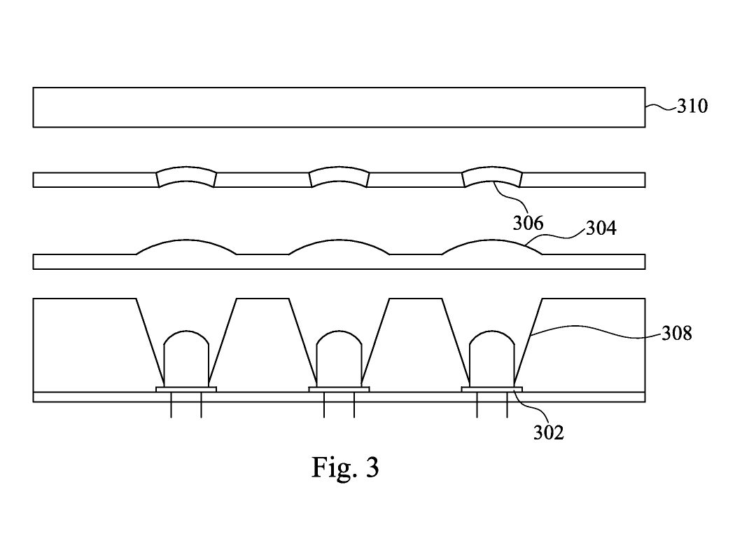

FIG. 3 depicts a schematic drawing of light emitting module according to one embodiment of this invention. As shown in FIG. 3, the light emitting module in the embodiment includes a light unit, an optical convergence lens array 304, a reflecting substrate 308 and a wavelength converting element array 306. In which, the light unit includes a light emitting diode chip array 302. In one embodiment of the present invention, every light emitting diode chip array 302 includes encapsulating glue covering every light emitting diode chips. Refer to FIG. 1 and FIG. 2, the light emitting diode chip array 302 emits first light in wavelength λ₁, then the first light in wavelength λ₁ passing through the optical convergence lens array 304. The first light is converged to a specific area and becoming a second light in wavelength λ₁, after passing through the optical convergence lens array 304. The second light is first emitted from the optical convergence lens array 304, then irradiate on the incident plane of the wavelength converting element array 306.

Because the wavelength converting element array 306 includes a wavelength converting material, after entering the incident plane and passing through the wavelength converting element array 306, the second light in wavelength λ₁ is converted to a third light in wavelength λ₂. Then, the third light after being received and passing through wavelength converting element array 306, entering a diffusion element 310 to diffuse and unify the third light.

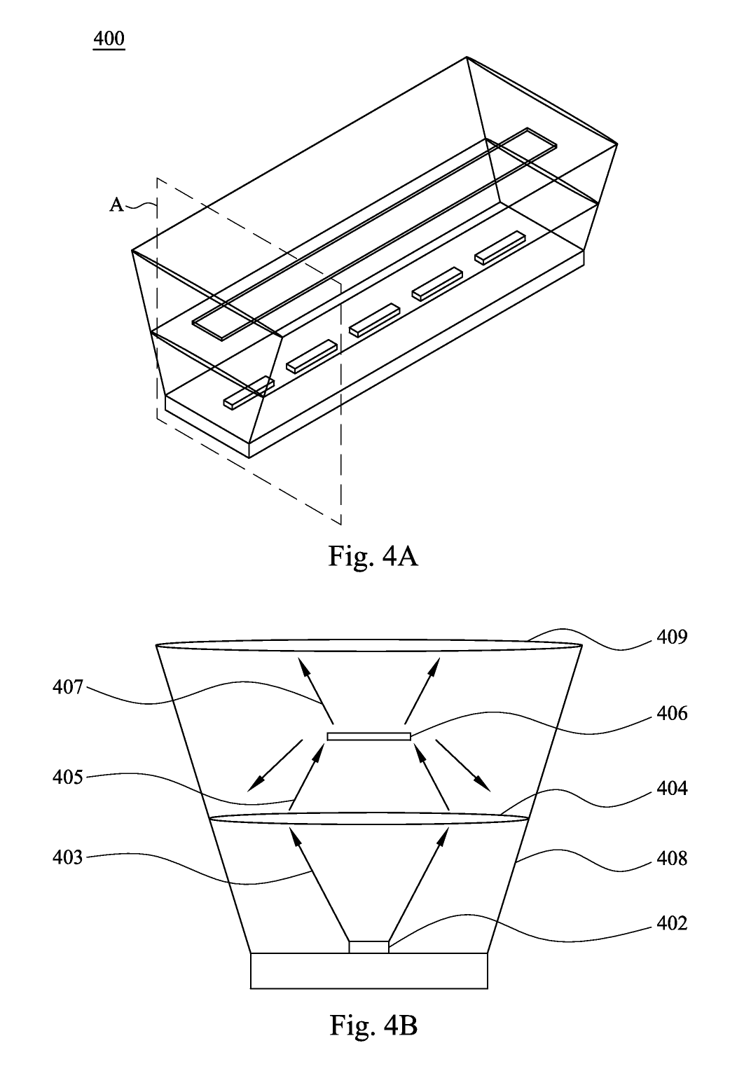

FIG. 4A and FIG. 4B depict schematic diagrams of light emitting module using in a strip lamp according to one embodiment of this invention. FIG. 4B is a cross-sectional view of strip lamp 400 plane A in FIG. 4A.

As shown in FIG. 4B, the strip lamp 400 includes a light-emitting unit, an optical convergent lens 404, an optical reflecting element 408 and a strip-shape wavelength converting element 406. Abovementioned light-emitting unit includes a plurality of light emitting diodes 402 arranged in lines. Refer to FIG. 1 and FIG. 2, a plurality of light emitting diode chips emit first light, then the first light in wavelength λ₁ passing through the optical convergence lens 404. The first light is converged to a specific area and becoming a second light in wavelength λ₁, after passing through the optical convergence lens 404. The optical convergence lens 404 is on the top of the light emitting diode chips, covering all the irradiation range with the emission angle of the light emitting diode chips 402. For example, the emission angle of the light emitting diode chip 402 can be 120 degrees, and the optical convergence lens 404 can cover the irradiation range for at least 120 degree for the light emitting diode chip 402. After that, the second light irradiate on the incident plane of the strip-shape wavelength converting element 406, after being emitted from the optical convergence lens 404.

Because the strip-shape wavelength converting element 406 includes a wavelength converting material, after entering the incident plane and passing through the strip-shape wavelength converting element 406, the second light in wavelength λ₁ is converted to a third light in wavelength λ₂. Then, the third light after being received and passing through the strip-shape wavelength converting element 406, entering a diffusion lens 409 to diffuse and unify the third light.

In some embodiments, the light emitting diode chip 402 may be a light emitting diode chip which emits blue or ultraviolet light in wavelength λ₁. The strip-shape wavelength converting element 406 can contain a wavelength converting material, which convert λ₁ to λ₂ , where λ₂ is larger than λ₁. To be specific, the light emitting diode chip 402 emits a light having wavelength λ₁ (e.g., short wavelength light like ultraviolet light or blue light), which can excite the wavelength converting element, making the light having wavelength λ₁ (e.g., ultraviolet light or blue light) convert to a light having wavelength λ₂ (e.g., red light, green light or yellow light) after passing through the strip-shape wavelength converting element 406.

For example, when the light emitting diode chip 402 emits ultraviolet light, the wavelength converting element can emit phosphor, which is selected from the group consisting of red color, green color, blue color, and combinations thereof, to convert the ultraviolet light to the different color emergent light. In one embodiment of the invention, the wavelength converting material is selected from the group consisting of phosphor, dye, pigments, quantum dots (QDs) and combinations thereof.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting module, comprising:
a light-emitting unit having a light-emitting element emitting a first light in a wavelength λ₁;
an optical convergent element, disposed in a light path of the first light from the light-emitting element, such that the first light of the wavelength λ₁, after passing through said optical convergent element, is converged to a specific area of a second light in a wavelength λ₁; and
a wavelength converting element, disposed in a light path of the second light from the optical convergent element, the wavelength converting element having a wavelength converting material and an incident plane, so that the second light in the wavelength λ₁, after entering the incident plane and the wavelength converting element, is converted to a third light in a wavelength λ₂.

2. The light emitting module of claim 1, further comprising a reflecting element, surrounding the light emitting unit and directing the first light in the wavelength λ₁ emitted from the light-emitting element to be reflected first by the reflecting element, and then to enter the optical convergent element.

3. The light emitting module of claim 1, further comprising a diffusion element, disposed on the top of the emitting direction of the third light in wavelength λ₂, to uniformly diffuse and receive the third light in wavelength λ₂, which passing through said wavelength converting element.

4. The light emitting module of claim 1, wherein the area of the incident plane on the wavelength converting element, substantially equal to the specific area of the second light in wavelength λ₁, which comes from the optical convergent element.

5. The light emitting module of claim 4, wherein the wavelength converting element comprising:
a body; and
at least one wavelength converting material, separating in the body in an uniform or patterned or laminar way.

6. The light emitting module of claim 5, wherein the wavelength converting material is one selected from the group consisting of phosphor, dye, pigments, quantum dots (QDs) and combinations thereof.

7. The light emitting module of claim 6, wherein the phosphor is a phosphor capable of emitting visible light.

8. The light emitting module of claim 7, wherein the phosphor is capable of emitting the visible light in a color selected from the group consisting of red, green, blue and combinations thereof.

9. The light emitting module of claim 5, wherein the body is in a plate or an arcuate structure.

10. The light emitting module of claim 1, wherein the light-emitting element is a light emitting diode chip.

11. The light emitting module of claim 10, wherein the light emitting diode chip is an ultraviolet light chip or a blue light chip.

12. The light emitting module of claim 1, wherein the optical convergent element is a condensing lens.

13. The light emitting module of claim 12, wherein the condensing lens is one selected from the group consisting of a convex lens, spherical lens, hemispherical lens, spherocylinder lens, cylindrical lens, molded lens, Fresnel lens and combinations thereof.

14. The light emitting module of claim 13 wherein the convex lens is one selected from the group consisting of plane-convex lens, double-convex lens, concave-convex lens and combinations thereof.

15. The light emitting module of claim 1, further comprising an encapsulating glue, covering the light-emitting element.
